(19) United States
(12) Patent Application Publication
(10) Pub. No.: US 2024/0087957 A1
(43) Pub. Date: Mar. 14, 2024

(54) Large Surface VBPR for Robust Alignment in Advanced Technology Nodes

(71) Applicant: International Business Machines Corporation, Armonk, NY (US)

(72) Inventors: Tsung-Sheng Kang, Ballston Lake, NY (US); Oscar van der Straten, Guilderland Center, NY (US); Koichi Motoyama, Clifton Park, NY (US); Alexander Reznicek, Troy, NY (US)

(21) Appl. No.: 17/943,564

(22) Filed: Sep. 13, 2022

(51) Int. Cl. H01L 21/768; H01L 23/522; H01L 23/528; H01L 27/088

(52) U.S. Cl. CPC H01L 21/76898; H01L 21/76831; H01L 23/5226; H01L 23/5286; H01L 27/088

(57) ABSTRACT

A semiconductor device comprising a contact comprising a first section and a second section; wherein the first section of the contact is located on a front side of a source or drain; wherein the second section extends from the front side of the source or drain to a backside of the source or drain; wherein the second section of the contact is comprised of a via and a connection area; wherein the via has a first width and the connection area has a second width, and wherein the second width is larger than the first width.

### BACKGROUND

The exemplary embodiments described herein relate generally to semiconductor device design and integrated circuit design, and more specifically, to a large surface VBPR for robust alignment in advanced technology nodes.

The examples described herein facilitate process integration, where aligning and landing of the BPR to VBPR is simplified, as the VBPR contact region is much larger due to the herein described structure. A larger cross section is provided (and a more easily engineered configuration) for the VBPR, which reduces contact resistance between the BPR and the VBPR.

### BRIEF SUMMARY

In one aspect, a semiconductor device includes a contact comprising a first section and a second section; wherein the first section of the contact is located on a front side of a source or drain; wherein the second section extends from the front side of the source or drain to a backside of the source or drain; wherein the second section of the contact is comprised of a via and a connection area; wherein the via has a first width and the connection area has a second width, and wherein the second width is larger than the first width.

In another aspect, a method includes forming, within a wafer, a via etch into at least an isolation layer; removing a portion of the isolation layer next to the etch, to increase a connection area of a via to be larger than a transfer section of the via; filling the via etch with metal to form the via; filling the removed portion of the isolation layer with metal to form the connection area of the via; forming a backside power rail; and connecting the connection area of the via to the backside power rail.

In another aspect, a method of forming a semiconductor device includes forming, within a wafer, a contact etch into at least an isolation layer; forming a contact at least partially within the contact etch, the contact comprising a first section and a second section; forming the first section of the contact to be located on a front side of a source or drain; forming the second section of the contact to extend from the front side of the source or drain to a backside of the source or drain; forming the second section of the contact to comprise a via and a connection area; and forming the via to have a first width and the connection area to have a second width, wherein the second width is larger than the first width.

In another aspect, a semiconductor device includes a backside power rail; a source or drain; and a via to connect the source or drain to the backside power rail, the via comprising a transfer section having a first width and a connection area having a second width, the second width larger than the first width; wherein the connection area of the via is curved from at least a surface of the transfer section to a portion of the connection area that joins to the backside power rail, to vary the second width of the connection area towards the backside power rail.

### BRIEF DESCRIPTION OF THE SEVERAL VIEWS OF THE DRAWINGS

The foregoing and other aspects of exemplary embodiments are made more evident in the following Detailed Description, when read in conjunction with the attached Drawing Figures, wherein:

FIG. 1 depicts a preliminary wafer;

FIG. 2 depicts VBPR RIE;

FIG. 3 depicts forming a nitride spacer;

FIG. 4 depicts completing the VBPR RIE;

FIG. 5 depicts STI/SiN liner removal;

FIG. 6 depicts two options for liner deposition, metal fill, CMP, and CA formation;

FIG. 7 depicts continuation of formation of the CA to complete the MOL module, completion of the BEOL module and bonding to a carrier wafer;

FIG. 8 depicts wafer flipping and substrate thinning;

FIG. 9 depicts silicon recessing;

FIG. 10 depicts the final structure of a first embodiment;

FIG. 11 shows a comparison between the final structure of the first embodiment and a conventional structure;

FIG. 12 depicts an ILD layer, STI layer and substrate;

FIG. 13 depicts VBPR RIE;

FIG. 14 depicts forming a nitride spacer;

FIG. 15 depicts completing the VBPR RIE;

FIG. 16 depicts STI removal, wetting, CMP, and removing the top HM;

FIG. 17 depicts liner deposition, metal filling and CMP;

FIG. 18 depicts the final structure of a second embodiment;

FIG. 19 shows a comparison between the final structure of the second embodiment and a conventional structure;

FIG. 20 depicts forming a locally deeper STI trench;

FIG. 21 depicts first STI formation;

FIG. 22 depicts continuing POR flow and a view after ILD;

FIG. 23 depicts VBPR RIE;

FIG. 24 depicts selectively removing a first STI;

FIG. 25 depicts forming a CA to complete an MOL module;

FIG. 26 depicts wafer flipping and substrate thinning;

FIG. 27 depicts Si recessing;

FIG. 28 depicts the final structure of a third embodiment;

FIG. 29 shows a comparison between the final structure of the third embodiment and a conventional structure;

FIG. 30 depicts first STI formation;

FIG. 31 depicts second STI formation;

FIG. 32 depicts formation of an ILD layer;

FIG. 33 depicts VBPR RIE;

FIG. 34 depicts selectively removing the first STI layer;

FIG. 35 depicts forming a CA to complete the MOL module;

FIG. 36 depicts wafer flipping and substrate thinning;

FIG. 37 depicts Si recessing;

FIG. 38 depicts a final structure of a fourth embodiment;

FIG. 39 shows a comparison between the final structure of the fourth embodiment and a conventional structure;

FIG. 40 is a logic flow diagram to fabricate a device, based on the examples described herein; and

FIG. 41 is a logic flow diagram to fabricate a device, based on the examples described herein.

### DETAILED DESCRIPTION

The term “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

Described herein is a semiconductor device comprising a contact that includes a first section and a second section, wherein the first section of the contact is located on a frontside of a source/drain, wherein the second section extends from the frontside of the source/drain to the backside of the source/drain, wherein the second section of the contact is comprised of a via and connection area, wherein the via has a first width and the connection area has a second width, and wherein the second width is larger than the first width.

In particular, described herein is a large surface VBPR for robust alignment in advanced technology nodes. In a first embodiment, the process flow includes forming a VBPR trench into an STI layer, partially removing the STI layer, and VBPR metallization. At the VBPR, part of the STI layer is replaced with the VBPR body. The cross-section area between the VBPR and the BPR is determined by a bottom area of the STI layer. The depth of the enlarged VBPR into the BPR is adjustable by varying the thickness of the STI being replaced.

There are several high value attributes and technical effects of the first embodiment and the examples described herein. For example, the herein described examples are easier for process integration, where aligning and landing of the BPR to VBPR is simplified, as the VBPR contact region is much larger due to the herein described structure. The herein described structure provides a larger cross section (and a more easily engineered configuration) for the VBPR, which reduces contact resistance between the BPR and the VBPR. Further, there is no liner inside the VBPR for current traveling from the BEOL metal layer to the BPR.

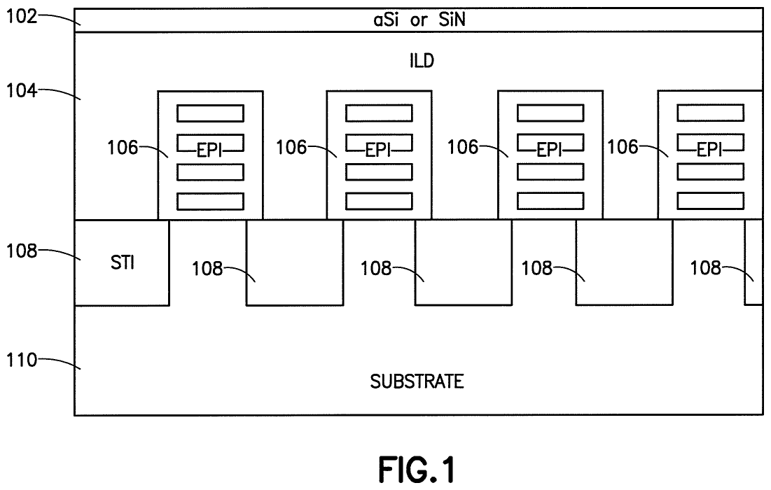

FIG. 1 depicts a preliminary wafer 100. The wafer 100 includes an aSi or SiN layer 102, an ILD layer 104, a plurality of epi based gates 106, an STI layer 108, and a substrate 110. In an embodiment, the STI layer 108 and the ILD layer 104 are HDP oxide.

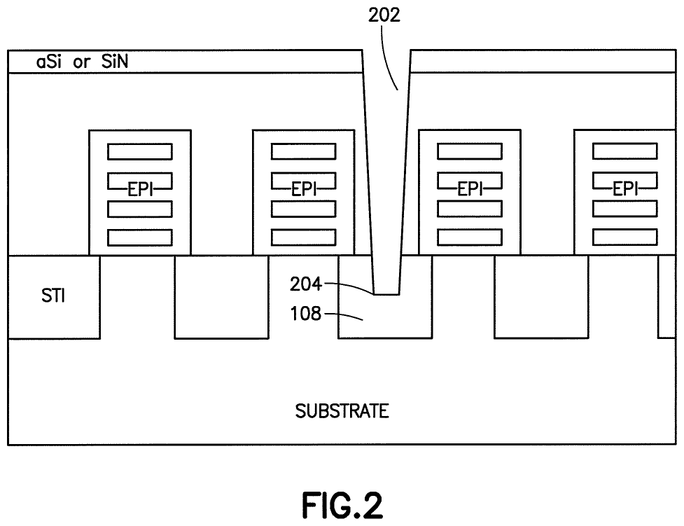

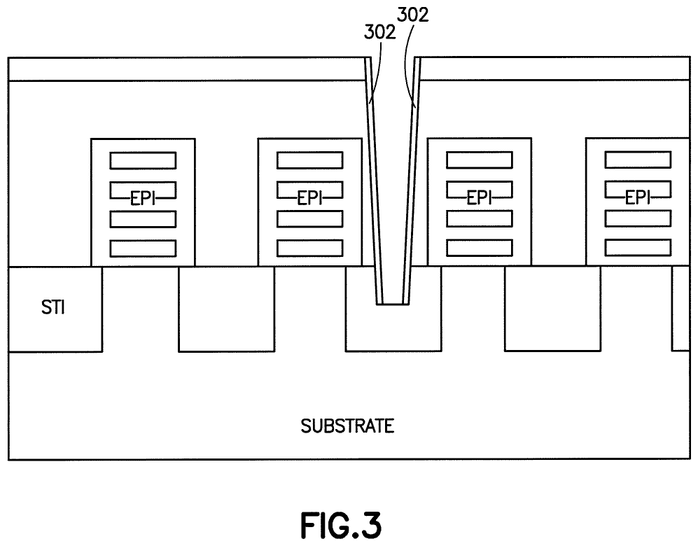

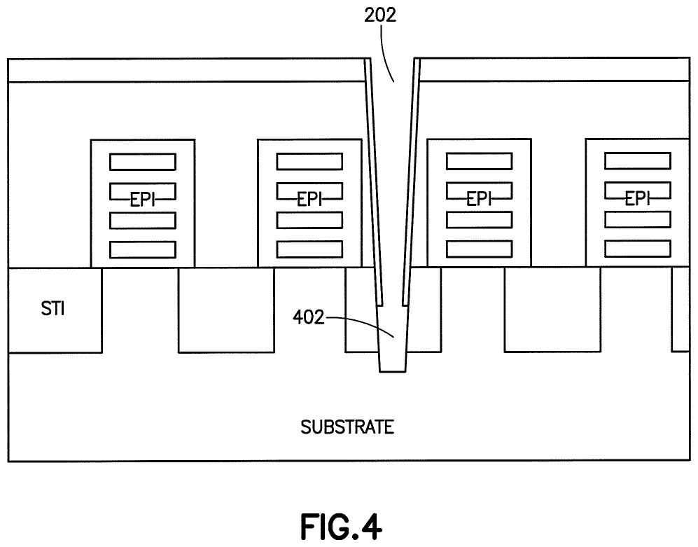

FIG. 2 depicts VBPR RIE 202. The VBPR RIE 202 stops (at 204) approximately halfway into the STI layer 108. FIG. 3 depicts forming a nitride spacer (302) within the VBPR RIE 202 on both sides. A portion of the nitride spacer 302 contacts the layer 102, the ILD layer 104, and the STI layer 108. FIG. 4 depicts completing the VBPR RIE 202 with additional etch 402. In the embodiment shown in FIG. 4, additional etch 402 of VBPR RIE 202 is partially into STI layer 108 and partially into the substrate 110.

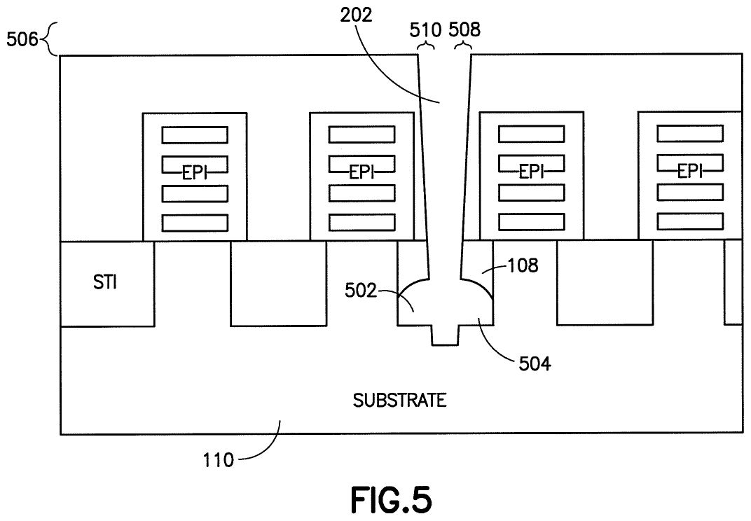

FIG. 5 depicts removal of a portion of the STI layer 108, shown by items 502 and 504. Optionally, the portion of the STI layer 108 may be removed by wetting the STI layer 108. Wetting and CMP is also done to remove the top HM 102 (e.g. the SiN layer), shown by item 506. Shown also in FIG. 5 is removal of the SiN liner, corresponding to the nitride spacer 302, as depicted with items 508 and 510. Optionally, the SiN liner may be removed by wetting.

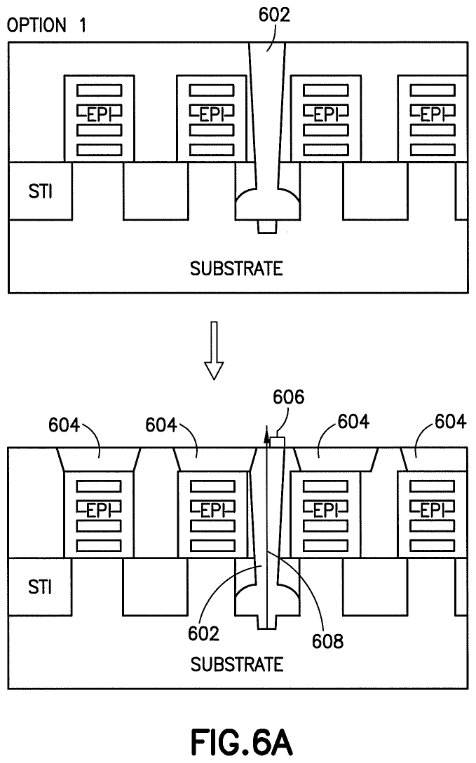

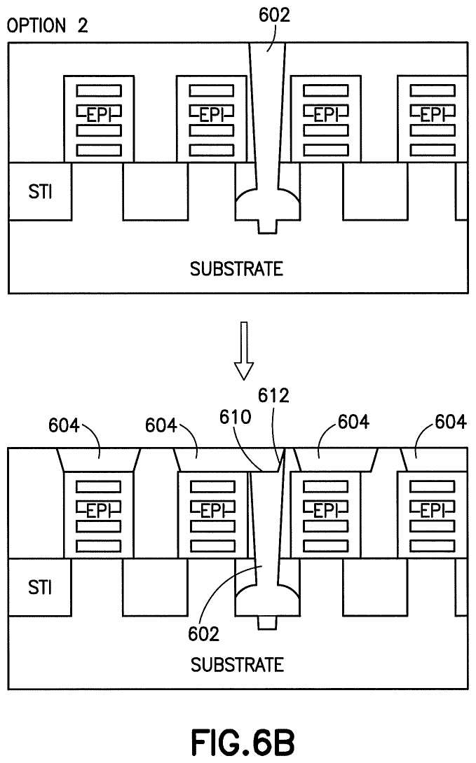

FIG. 6 depicts two options for liner deposition, metal fill, CMP, and CA formation. In both options, etch 202 is filled with metal 602, the area where the STI layer was removed (502, 504) is filled with metal, and a plurality of CA (each given as 604) are formed within ILD layer 104, and the CA (604) are joined to the epi gates 106. In the first option, there is lower resistance as there is no liner between the BPR and future metal connection. Refer to the absence of liner (given as 606) and arrow 608. In option 2, there is additional liner (610, 612) within the metal fill 602.

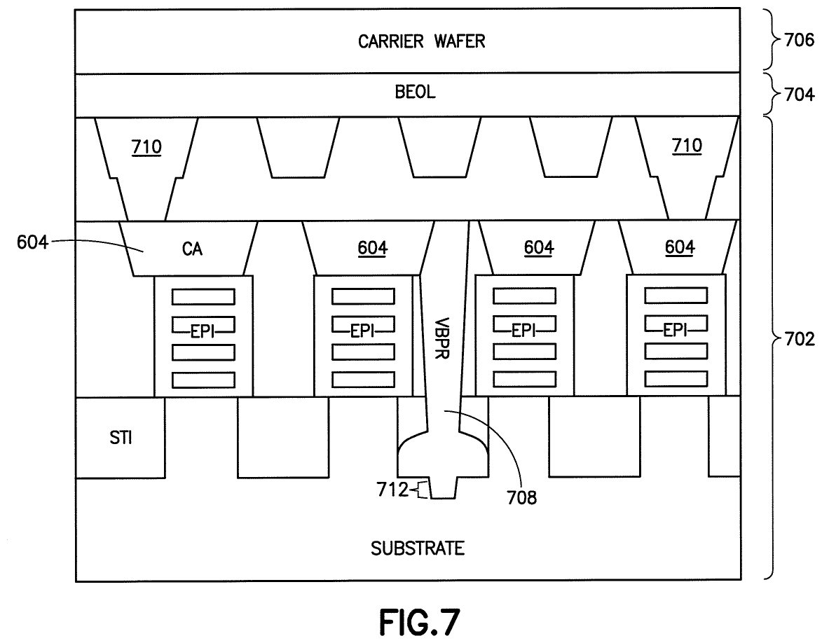

FIG. 7 depicts continuation of formation of the CA 604 to complete the MOL module 702, completion of the through BEOL module 704 and bonding the BEOL module 704 to a carrier wafer 706. The VBPR is depicted as item 708. A portion (712) of the VBPR is subsequently thinned. Vias (710) couple the CA (604) to the BEOL module 704.

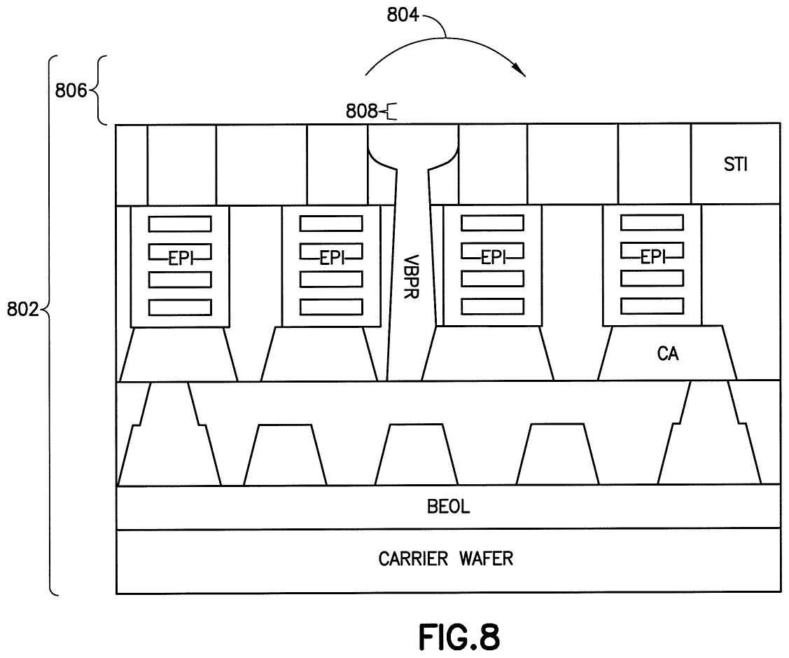

FIG. 8 depicts wafer flipping and substrate thinning. The wafer (802) is flipped (804) so that the carrier wafer 706 is on the bottom and the VBPR 708 is near the top. The substrate 110 is thinned, depicted by removed or thinned substrate portion 806. The portion 712 of the VBPR 708 is also thinned, depicted by removed VBPR portion 808.

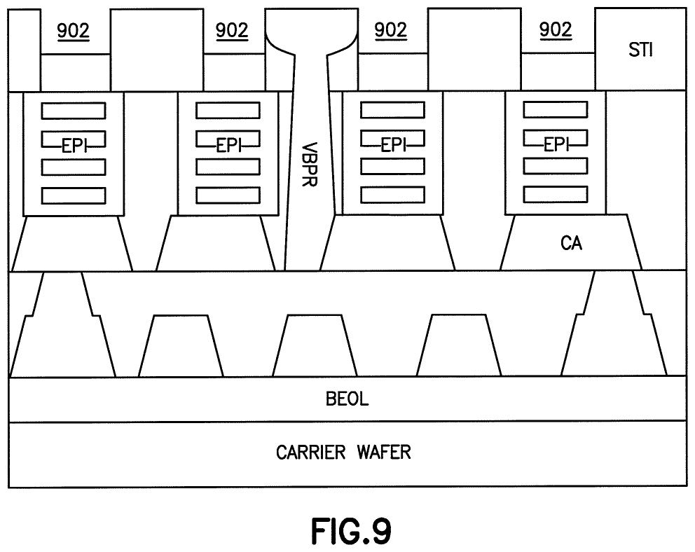

FIG. 9 depicts silicon recessing to generate recesses 902 within the silicon layer 110 residing between the STI layer 108 and between the STI layer 108 and VBPR 708.

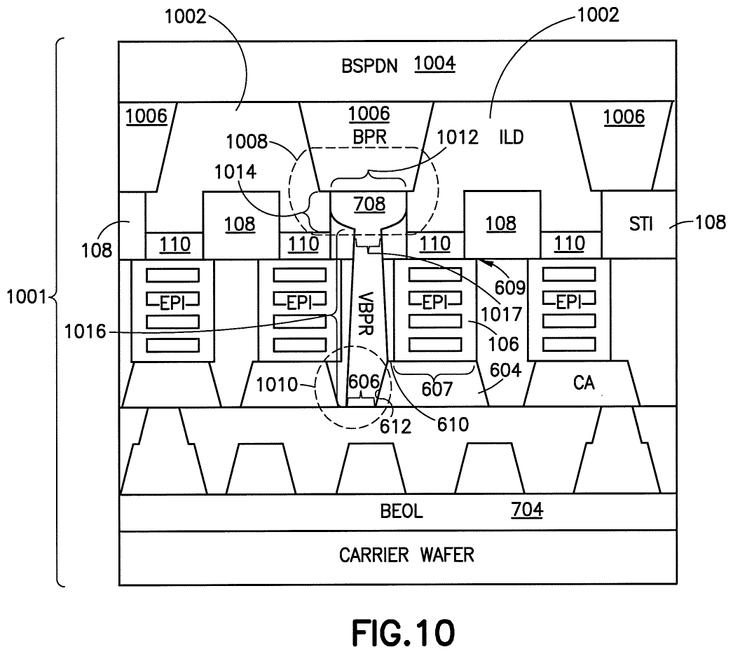

FIG. 10 depicts the final structure 1001 of this embodiment. The final structure 1001 is formed as a result of filling an ILD layer 1002, formation of BPR 1006, and formation of BSPDN 1004. ILD layer 1002 encapsulates a portion of BPR 1006 and is applied between a portion of STI layer 108, a portion of substrate 110, and a portion of BSPDN 1004. BPR 1006 is formed on a surface of VBPR 708. BSPDN 1004 is at least partially coupled to BPR 1006. FIG. 10 also shows a connection area 1014 of the via 708 and a transfer section 1016 of the via 708.

In FIG. 10, a contact (comprising the VBPR 708 and contact 604) has a first section (604) located on a front side 607 of the source/drain 106, the source/drain 106 also having a backside 609. Cross section 1012 of VBPR 708 is greater than cross-section 1017 of the VBPR 708. The source/drain 106 is the epi itself. The CA 604 is the connector toward source/drain 106.

A main benefit of the final structure 1001 is the overlay 1008 between the VBPR 708 and the BPR 1006 can be more robust with an enlarged area. There is less resistance with greater cross-section 1012. Also, referring to item 1010, there is no liner between 708 VBPR and the BPR 1006, resulting in better conductance. Regarding item 1010, refer also to option 1 shown in FIG. 6, namely absence of liner (given as 606) and arrow 608. An idea is to focus on VBPR to BPR or CA.

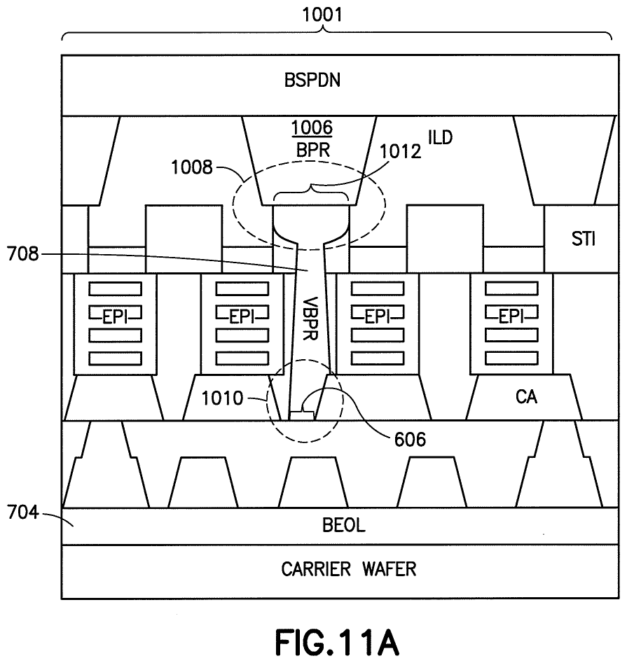

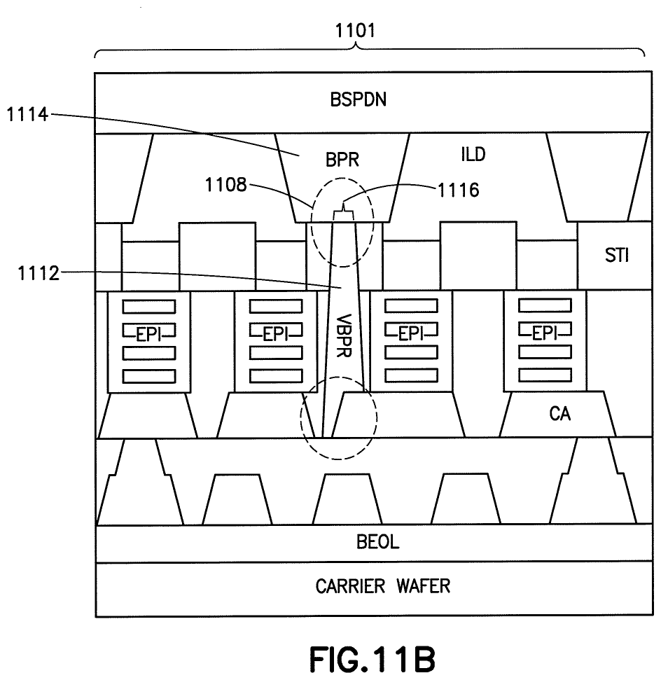

FIG. 11 shows a comparison between the final structure 1001 of the first embodiment and a conventional structure 1101. As can be seen in FIG. 11, the overlay 1008 between the VBPR 708 and the BPR 1006 of structure 1001 has a larger more robust area than the overlay 1108 between the VBPR 1112 and BPR 1114 of structure 1101. Thus there is less resistance with a greater cross section 1012 compared to cross section 1116.

In a second embodiment, a process flow includes fabrication of a VBPR trench into an STI layer, partially removing the STI layer, and VBPR metallization. A dielectric liner is applied at the sidewall of the VBPR. At the VBPR, part of the STI is replaced with the VBPR body. The cross-section area between the VBPR and BPR is determined by the STI layer's bottom area. The depth of the enlarged VBPR into the BPR is adjustable by varying the thickness of the STI being replaced. In this embodiment, a method includes local partial replacement of the STI layer with VBPR material.

There are several high value attributes and technical effects of the second embodiment and the examples described herein. For example, process integration is easier, as there is easier alignment between the VBPR and the BPR. There is also less concern of shorting between the VBPR and immediate epi/CA. There is a larger cross-section for the VBPR, which is more easily engineered. The larger cross-section for the VBPR also reduces contact resistance between the BPR and the VBPR. Also, in this embodiment, there is no metal liner inside the VBPR for current traveling across the VBPR.

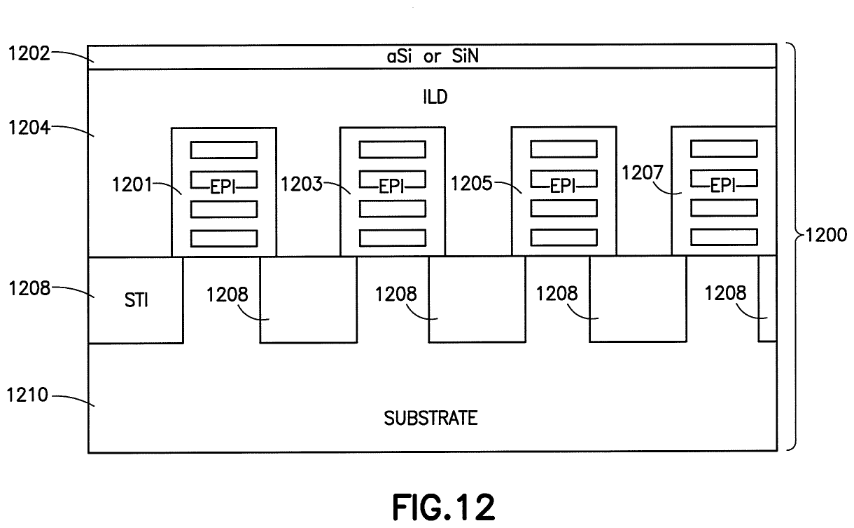

FIG. 12 depicts a preliminary wafer 1200. The wafer 1200 includes an aSi or SiN layer 1202, an ILD layer 1204, a plurality of epi based gates (1201, 1203, 1205, 1207), an STI layer 1208, and a substrate 1210. In an embodiment, the STI layer 1208 and the ILD layer 1204 are HDP oxide.

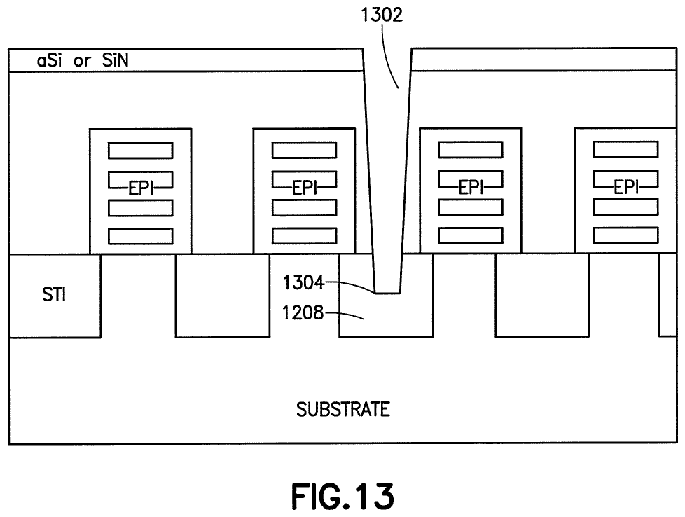

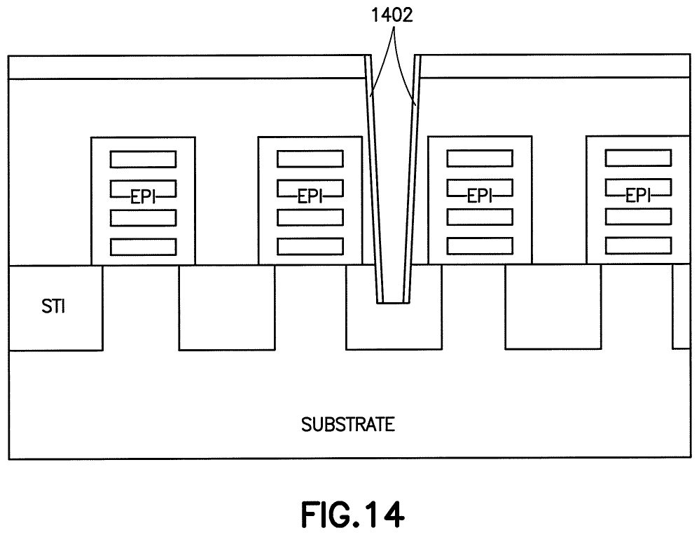

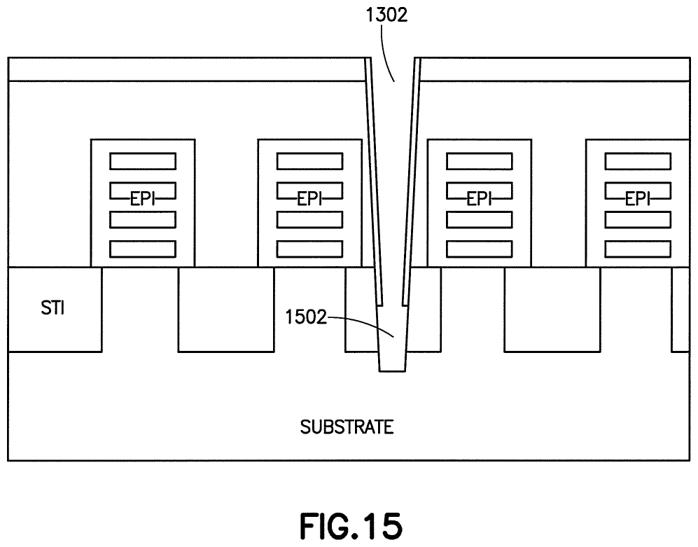

FIG. 13 depicts VBPR RIE 1302. The VBPR RIE 1302 stops (at 1304) approximately halfway into the STI layer 1208. FIG. 14 depicts forming a nitride spacer (1402) within the VBPR RIE 1302 on both sides. A portion of the nitride spacer 1402 contacts the layer 1202, the ILD layer 1204, and the STI layer 1208. FIG. 15 depicts completing the VBPR RIE 1302 with additional etch 1502. In the embodiment shown in FIG. 15, additional etch 1502 of VBPR RIE 1302 is partially into STI layer 1208 and the substrate 1210.

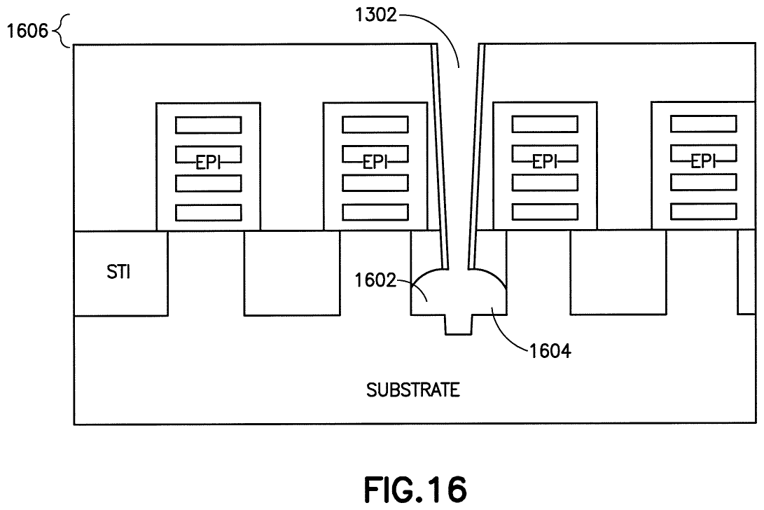

FIG. 16 depicts removal of a portion of the STI layer 1208, shown by items 1602 and 1604. The portion of the STI layer 1208 may be removed by wetting the STI layer 1208. Wetting and CMP is also done to remove the top HM 1202 (e.g. the SiN layer), shown by item 1606.

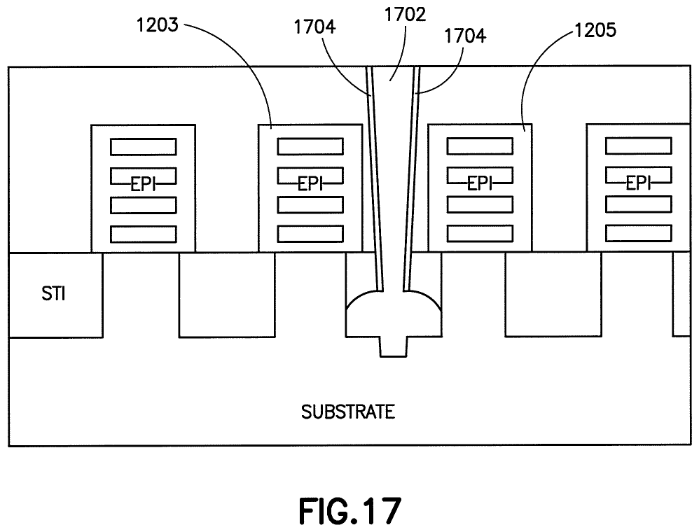

FIG. 17 depicts liner deposition, metal fill, and CMP. Etch 1302 is filled with metal 1702. Liner 1704 is formed and applied as shown to help isolate from immediate epi, namely epi 1203 and epi 1205. Liner 1704 is formed along the sides of the metal filling 1702 and within the ILD layer 1204 and STI layer 1208.

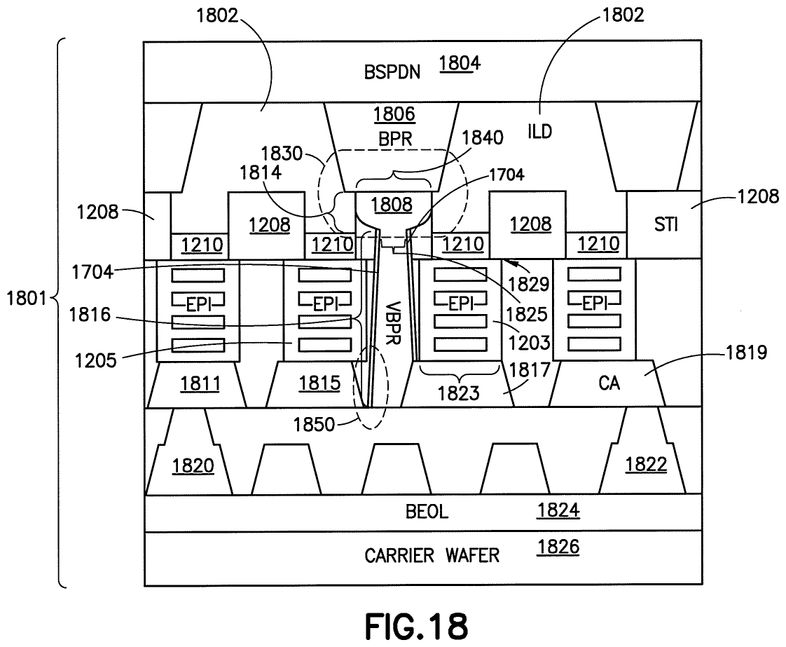

FIG. 18 depicts the final structure 1801 of this embodiment. The final structure 1801 is formed as a result of filling an ILD layer 1802, formation of BPR 1806, and formation of BSPDN 1804. ILD layer 1802 encapsulates a portion of BPR 1806 and is applied between a portion of STI layer 1208, a portion of substrate 1210, and a portion of BSPDN 1804. BPR 1806 is formed on a surface of VBPR 1808. BSPDN 1804 is at least partially coupled to BPR 1806. FIG. 18 also shows a connection area 1814 of the via 1808 and a transfer section 1816 of the via 1808.

In FIG. 18, a contact (comprising the VBPR 1808 and contact 1817) has a first section (1817) located on a front side 1823 of the source/drain 1203 (1817 is the connector to source/drain 1203 which is epi per se), the source/drain 1203 also having a backside 1829. Cross section 1840 of the VBPR 1808 is greater than cross-section 1825 of the VBPR 1808.

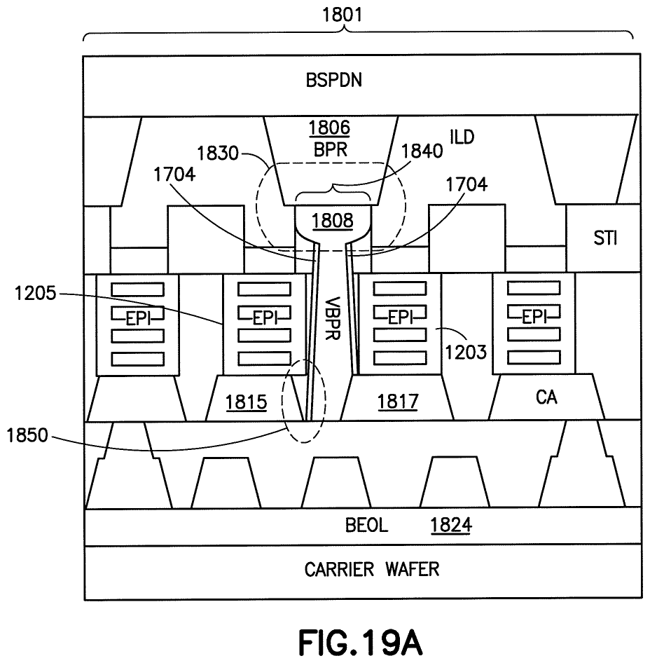

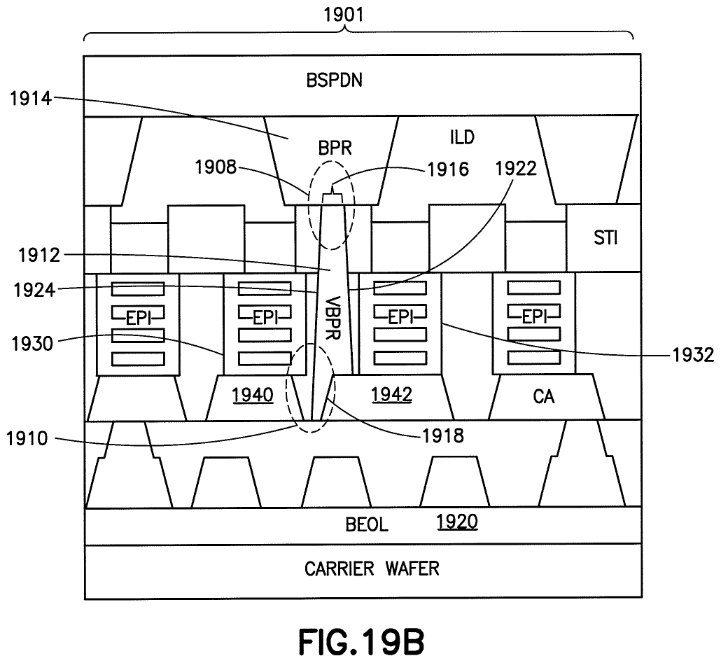

Compared to the first embodiment described with respect to FIG. 1, FIG. 2, FIG. 3, FIG. 4, FIG. 5, FIG. 6, FIG. 7, FIG. 8, FIG. 9, FIG. 10, and FIG. 11, additional benefits of this second embodiment (FIG. 12, FIG. 13, FIG. 14, FIG. 15, FIG. 16, FIG. 17, FIG. 18, FIG. 19) include that the dielectric liner 1704 at the VBPR 1808 provides isolation from nearby epi (1203, 1205) and CA (1815, 1817). Other formed CA include CA 1811 and CA 1819, which are joined to BEOL 1824 with vias 1820 and 1822, respectively. BEOL 1824 is joined to carrier wafer 1826.

Similar to the benefit of the final structure 1001, a main benefit of the final structure 1801 is the overlay 1830 between the VBPR 1808 and the BPR 1806 can be more robust with an enlarged area. There is less resistance with greater cross-section 1840. Also, the interface between VBPR 1808 and BPR 1806 shows the absence of liner, which provides better conductance.

FIG. 19 shows a comparison between the final structure 1801 of the second embodiment and a conventional structure 1901. Compared to the first embodiment, additional benefits of this second embodiment include that the dielectric liner 1704 at the VBPR 1808 provides isolation from nearby epi (1203, 1205) and CA (1815, 1817). There is no dielectric liner at 1922 and 1924 to provide isolation from nearby epi (1930, 1932) and CA (1940, 1942) in structure 1901.

As also can be seen in FIG. 19, the overlay 1830 between the VBPR 1808 and the BPR 1806 of structure 1801 has a larger more robust area than the overlay 1908 between the VBPR 1912 and BPR 1914 of structure 1901. Thus there is less resistance with a greater cross section 1840 compared to cross section 1916. Further, there is no liner in region 1850 between the BEOL metal 1824 and the BPR 1806, resulting in better conductance compared to there being liner in region 1910 of structure 1901, given at least as item 1918, between the BEOL metal 1920 and the BPR 1914.

In a third embodiment, a process for fabricating a semiconductor device includes forming two STI layers, removing the first STI layer, and performing VBPR metallization. At the VBPR, part of the STI is replaced with a VBPR body. The cross-section area between the VBPR and BPR is determined by the STI's bottom area. The depth of the enlarged VBPR buried inside the BPR is adjustable by varying the thickness of the STI being replaced. A method includes forming two or more STI layers, and local partial replacement of the STI.

There are several significant high value attributes of the third embodiment. Process integration is easier, as aligning and landing of the BPR to VBPR is simplified, as the VBPR contact region is much larger due to the structure described herein. A larger more easily engineered cross-section for the VBPR is provided, which reduces contact resistance between the BPR and VBPR. There is even greater contact area between the BPR and VBPR. There is no metal line inside the VBPR for current traveling across the VBPR.

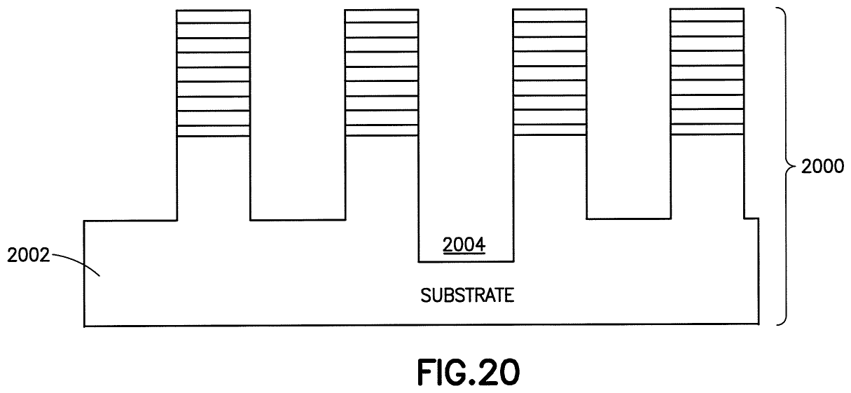

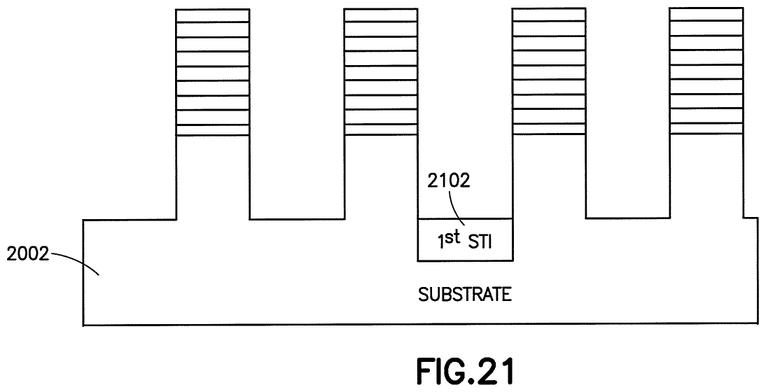

FIG. 20 depicts forming a locally deeper STI trench 2004 within substrate 2002 of a preliminary wafer 2000. FIG. 21 depicts first STI formation 2102 on substrate 2002. The first bottom STI 2101 may comprise SiN or TiO2. The process includes filling all trenches, CMP and timed recessing, leaving the first STI 2102 in deeper trenches.

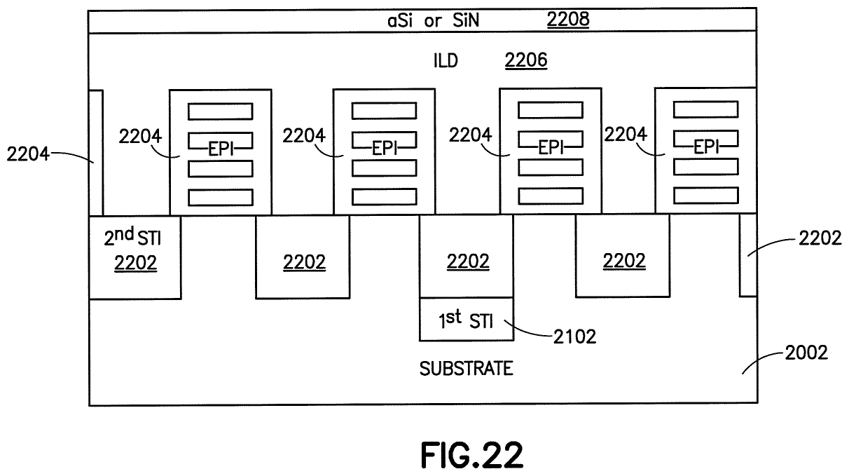

FIG. 22 depicts continuing POR flow and a view after ILD. A second STI layer 2202 is applied to the first STI layer 2101 and to the substrate 2002. A plurality of epi based gates (2204) are formed within an ILD layer 2206 to contact at least partially the second STI layer 2202 and the substrate 2002. An HM layer 2208 (aSi or SiN) is applied to the ILD layer 2206.

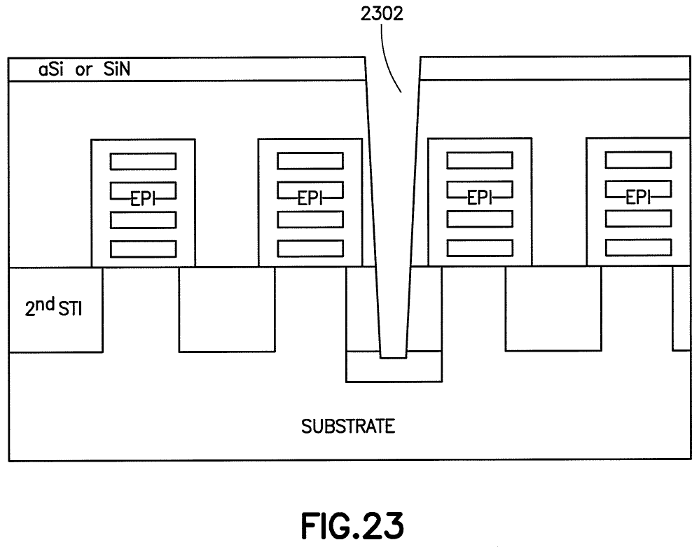

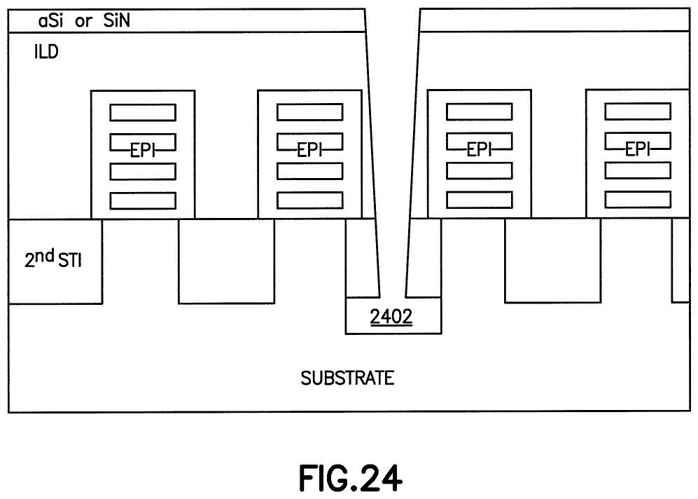

FIG. 23 depicts VBPR RIE 2302. The VBPR RIE 2302 is formed through HM layer 2208, ILD layer 2206, second STI layer 2202, and within first STI layer 2102. FIG. 24 depicts selectively removing the first STI 2102 to form region 2402.

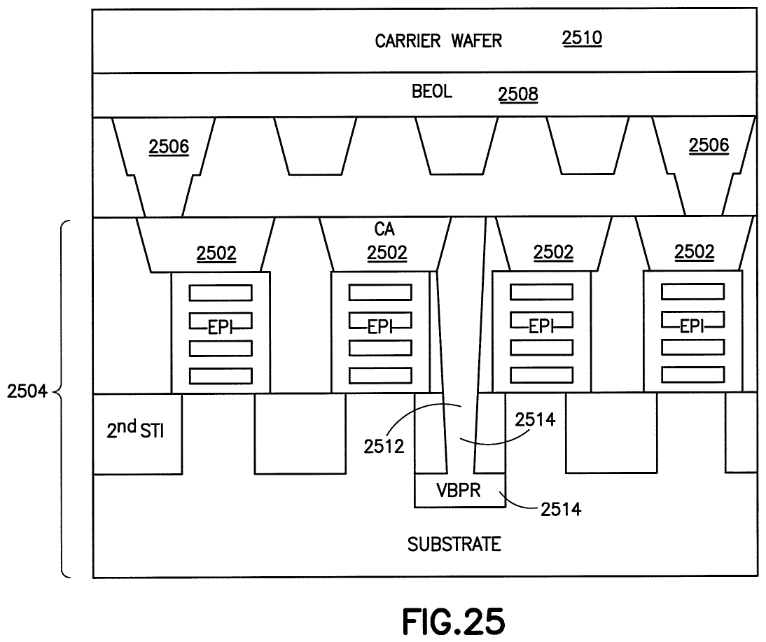

FIG. 25 depicts forming CA (2502) to complete an MOL module 2504. The BEOL module is 2508 is completed, followed by bonding the BEOL 2508 to the carrier wafer 2510. Vias 2506 couple the BEOL 2508 to the CA 2502. The VBPR 2512 is also completed by filling the VBPR RIE 2302 and region 2402 with metal 2514.

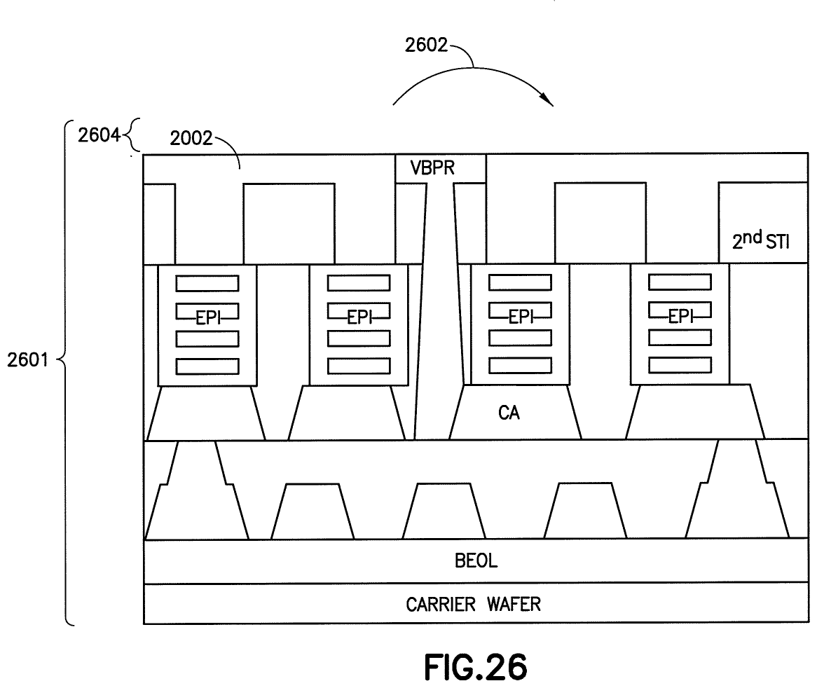

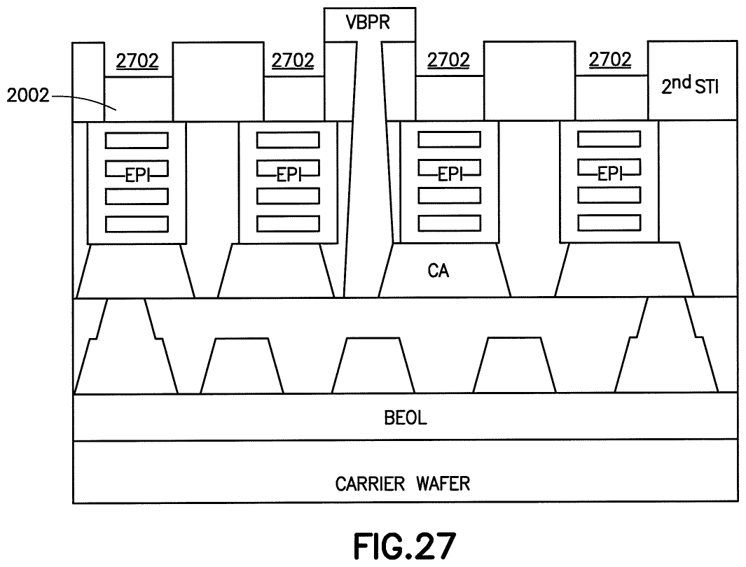

FIG. 26 depicts flipping 2602 the wafer 2601 and thinning the substrate 2002. The removed substrate, or reduction in substrate, is given as item 2604. FIG. 27 depicts recessing the Si layer 2002 to form etches 2702.

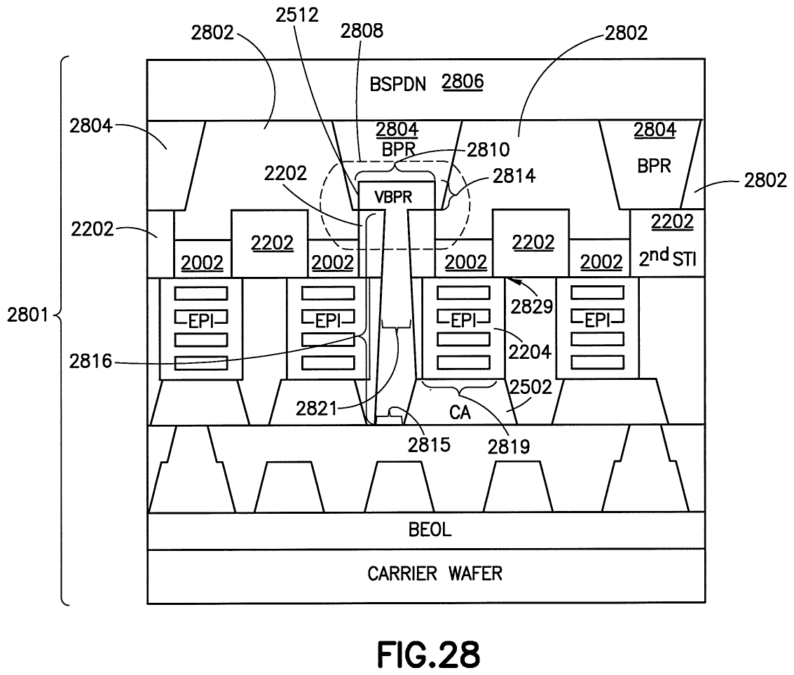

FIG. 28 depicts the final structure 2801 of the third embodiment. The final structure 2801 is formed as a result of filling an ILD layer 2802, formation of the BPR 2804, and formation of BSPDN 2806. The ILD layer 2802 encapsulates at least partially the BPR 2804 and is formed between the BSPDN 2806 and the second STI layer 2202 and substrate 2002. Shown in FIG. 28 is the overlay 2808 between the VBPR 2512 and BPR 2804. FIG. 28 also shows a connection area 2814 of the via 2512 and a transfer section 2816 of the via 2512.

In FIG. 28, a contact (comprising the VBPR 2512 and contact 2502) has a first section (2502) located on a front side 2819 of the source/drain 2204, the source/drain 2204 also having a backside 2829. Cross section 2810 of the VBPR 2512 is greater than cross-section 2821 of the VBPR 2512.

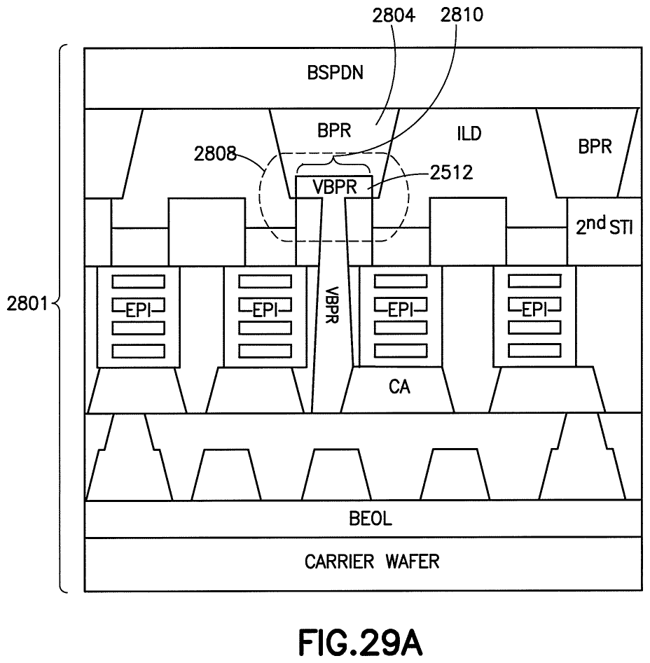

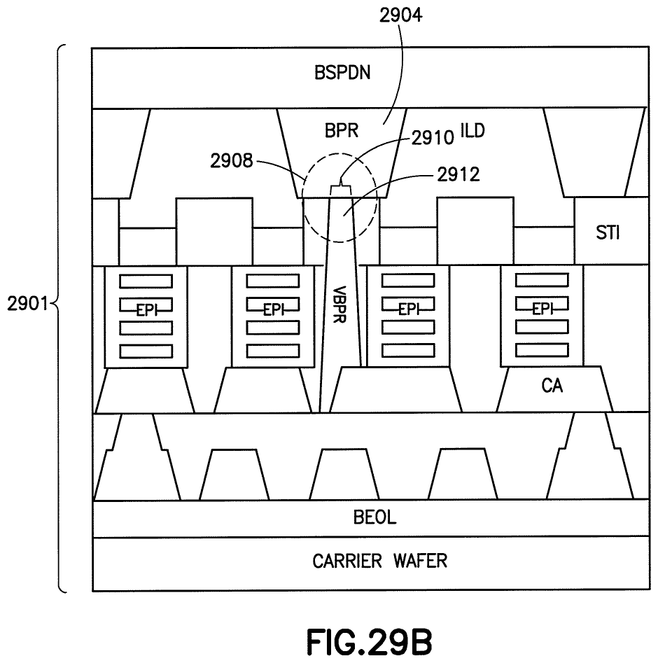

FIG. 29 depicts a comparison of the final structure 2801 of the third embodiment and a conventional structure 2901. The overlay 2808 between the VBPR 2512 and the BPR 2804 is larger, having a larger cross-section 2810, compared to the overlay 2908 between the VBPR 2912 and the BPR 2904 with cross-section 2910 of structure 2901.

In a fourth embodiment, two layers of STI are formed, the first layer of STI is locally removed, and a VBPR metallization is performed. A cross-section of the VBPR at its liner-free interface with the BPR is increased, which provides much better conductance. At the VBPR, part of the STI is replaced with the VBPR body. The cross-section area between the VBPR and the BPR is determined by the STI layer's bottom area. Certain STI areas not used for the VBPR formation consist of a two layered STI. In the fourth embodiment, two or more STI layers are formed, and there is a local partial replacement of one or more of the STI layers with VBPR material.

There are significant high value attributes and technical effects of the fourth embodiment, including easier process integration. Aligning and landing of the BPR to VBPR is simplified, as the VBPR contact region is much larger due to the structure. The structure provides a larger cross-section for the VBPR, which reduces contact resistance between the BPR and the VBPR. The structure is more easily engineered. There is no metal liner inside the VBPR for current traveling across the VBPR.

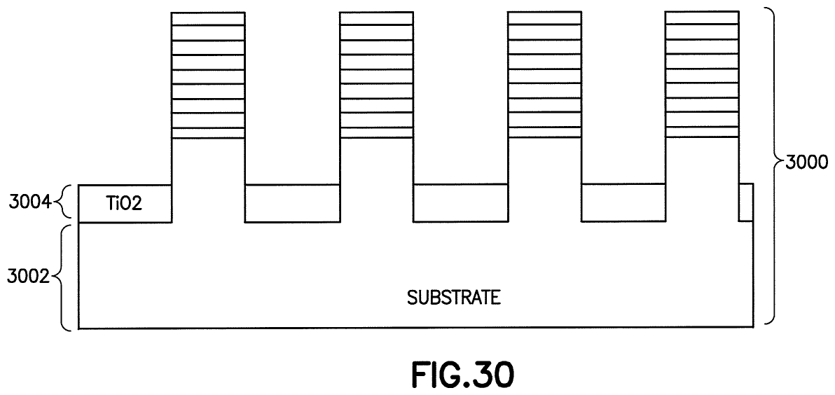

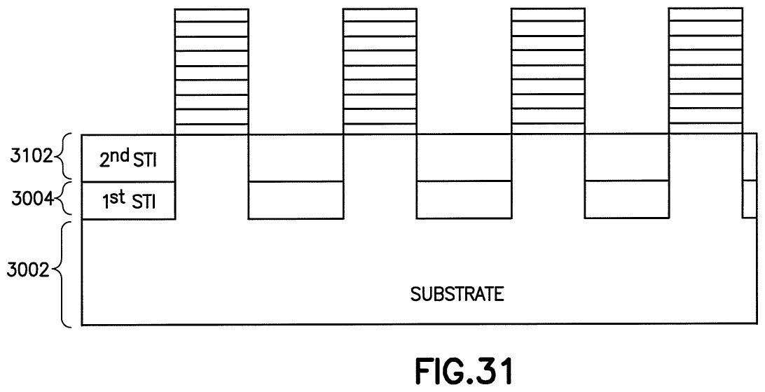

FIG. 30 depicts formation of a first STI layer 3004 over substrate 3002 of preliminary wafer 3000. First STI layer 3004 may be SiN or TiO2. FIG. 31 depicts formation of a second STI layer 3102 over the first STI layer 3004 and between substrate 3002. The second STI layer 3102 may comprise HDP oxide.

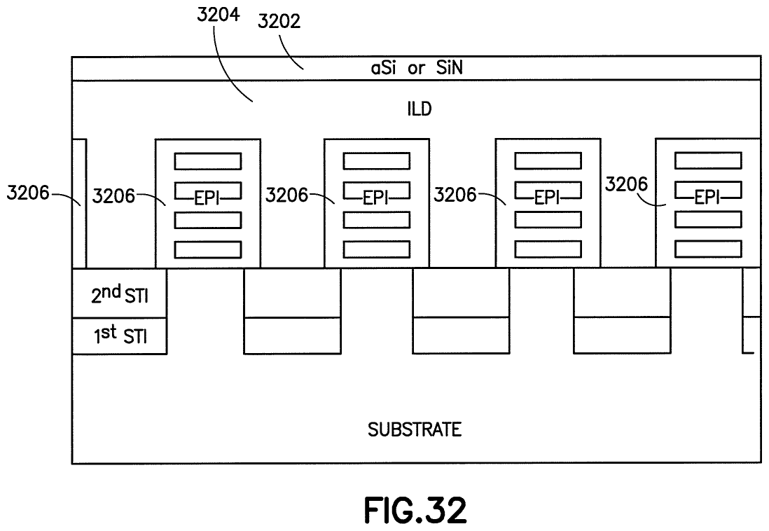

FIG. 32 depicts formation of an ILD layer 3204. An HM layer 3202 (aSi or SiN) is formed on the ILD layer 3204, which ILD layer 3204 encapsulates the epi based gates 3206 and is also formed partially next to the second STI layer 3102. The epi based gates 3206 are formed partially on the second STI layer 3102 and partially on substrate 3002.

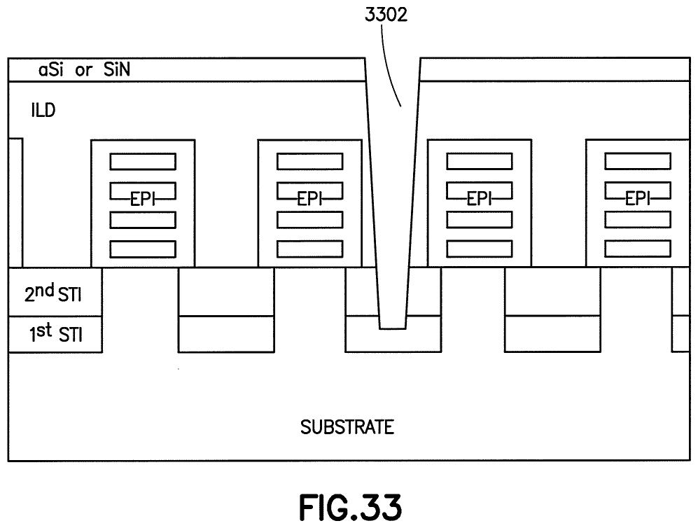

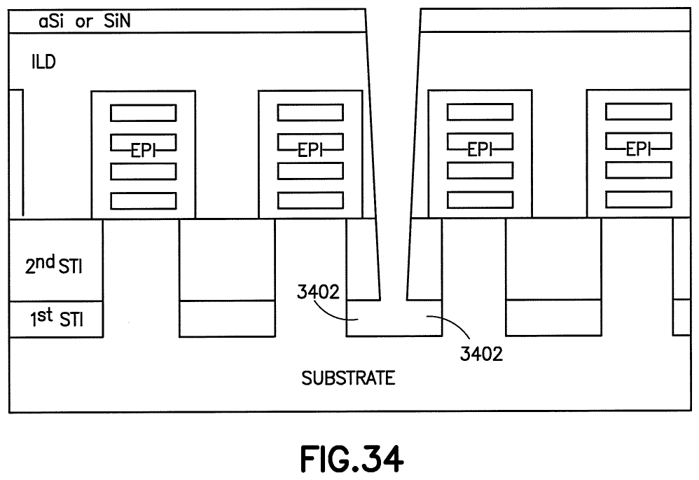

FIG. 33 depicts VBPR RIE 3302, which is formed through the HM layer 3202, the ILD layer 3204, the second STI layer 3102, and the first STI layer 3004. FIG. 34 depicts selectively removing the first STI layer 3004, resulting in region 3402.

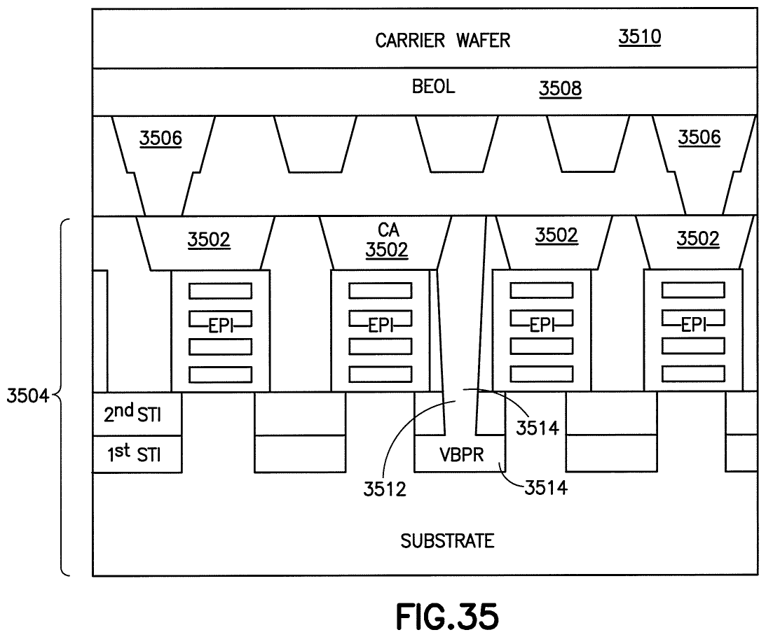

FIG. 35 depicts forming CA (3502) to complete an MOL module 3504. The BEOL module 3508 is completed, followed by bonding the BEOL 3508 to the carrier wafer 3510. Vias 3506 couple the BEOL 3508 to the CA 3502. The VBPR 3512 is also completed by filling the etch VBPR RIE 3302 and region 3402 with metal 3514.

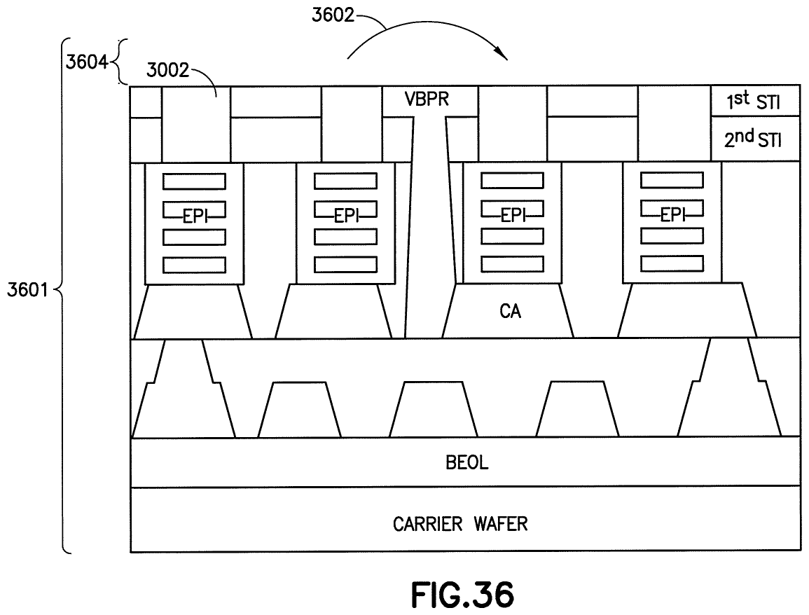

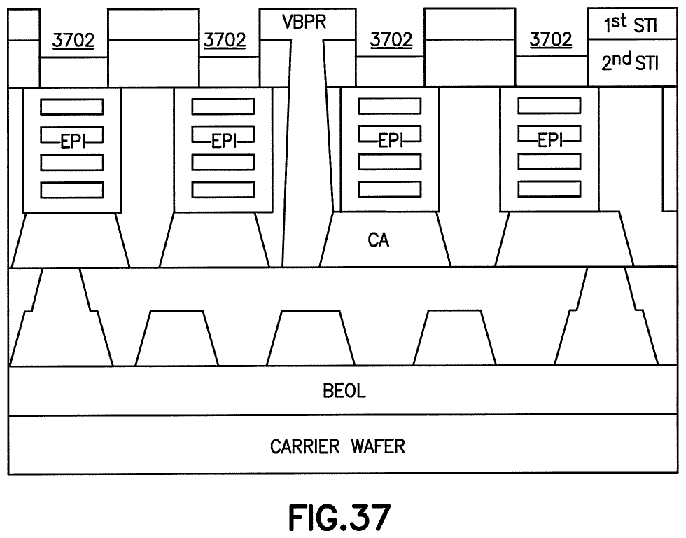

FIG. 36 depicts flipping 3602 the wafer 3601 and thinning the substrate 3002. The removed substrate, or reduction in substrate, is given as item 3604. FIG. 37 depicts recessing the Si layer 3002 to form etches 3702 between the first STI layer 3004 and the second STI layer 3102.

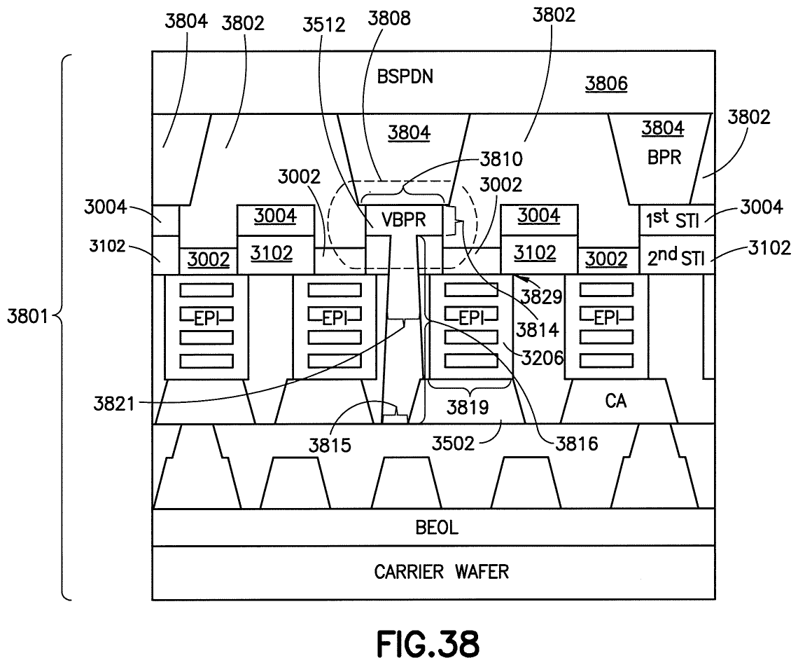

FIG. 38 depicts the final structure 3801 of the fourth embodiment. The final structure 3801 is formed as a result of filling an ILD layer 3802, formation of the BPR 3804, and formation of BSPDN 3806. The ILD layer 3802 encapsulates at least partially the BPR 3804 and is formed between the BSPDN 3806, first STI layer 3004, second STI layer 3102 and substrate 3002. Shown in FIG. 38 is the overlay 3808 between the VBPR 3512 and BPR 3804. FIG. 38 also shows a connection area 3814 of the via 3512 and a transfer section 3816 of the via 3512.

In FIG. 38, a contact (comprising the VBPR 3512 and contact 3502) has a first section (3502) located on a front side 3819 of the source/drain 3206, the source/drain 3206 also having a backside 3829. Cross section 3810 of the VBPR 3512 is greater than cross-section 3821 of the VBPR 3512. There is no liner at the interface 3810.

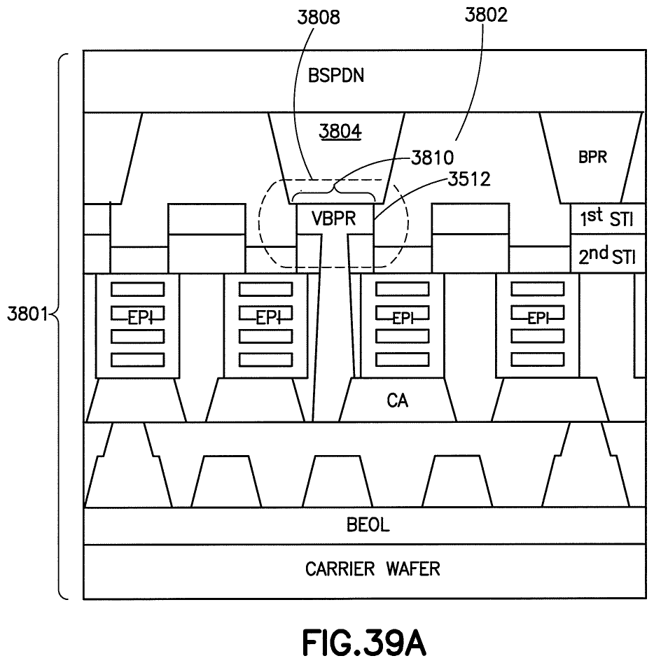

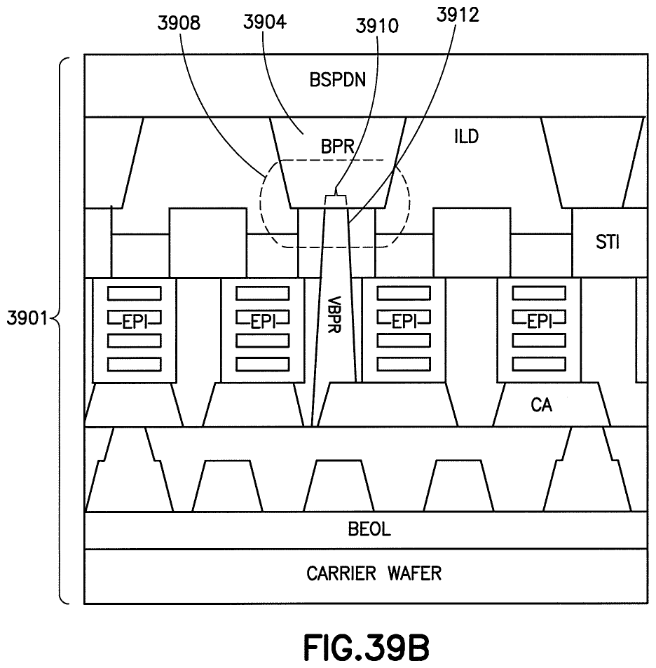

FIG. 39 depicts a comparison of the final structure 3801 of the fourth embodiment and a conventional structure 3901. The overlay 3808 between the VBPR 3512 and the BPR 3804 is larger, having a larger cross-section 3810, compared to the overlay 3908 between the VBPR 3912 and the BPR 3904 with cross-section 3910 of structure 3901.

Accordingly, described herein is a semiconductor device including a backside power rail, a source or drain, and a via to connect the source or drain to the backside power rail, the via comprising a transfer section having a first width and a connection area having a second width, the second width larger than the first width. The semiconductor device may further include a contact joined to a front side of the source or drain and to the via. The semiconductor device may further include dielectric liner along at least one sidewall of the via. The dielectric liner is configured to isolate the via from the source or drain. A cross-section area of the connection area between the via and the backside power rail is determined with a bottom area of an isolation layer. The transfer section extends from a front side of the source or drain to a backside of the source or drain. The semiconductor device further includes back end of line metal connected with the via to the backside power rail. The connection area of the contact connects the back end of line metal to the backside power rail without liner.

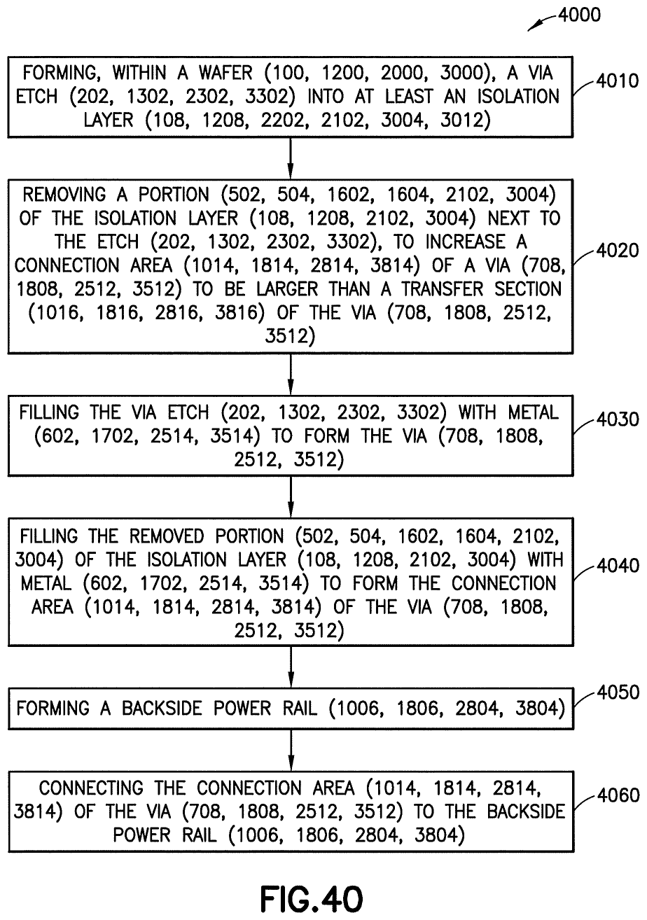

FIG. 40 is a logic flow diagram to form a device, based on the examples described herein. At 4010, the method includes forming, within a wafer (100, 1200, 2000, 3000), a via etch (202, 1302, 2302, 3302) into at least an isolation layer (108, 1208, 2202, 2102, 3004, 3012). At 4020, the method includes removing a portion (502, 504, 1602, 1604, 2102, 3004) of the isolation layer (108, 1208, 2102, 3004) next to the etch (202, 1302, 2302, 3302), to increase a connection area (1014, 1814, 2814, 3814) of a via (708, 1808, 2512, 3512) to be larger than a transfer section (1016, 1816, 2816, 3816) of the via (708, 1808, 2512, 3512). At 4030, the method includes filling the via etch (202, 1302, 2302, 3302) with metal (602, 1702, 2514, 3514) to form the via (708, 1808, 2512, 3512). At 4040, the method includes filling the removed portion (502, 504, 1602, 1604, 2102, 3004) of the isolation layer (108, 1208, 2102, 3004) with metal (602, 1702, 2514, 3514) to form the connection area (1014, 1814, 2814, 3814) of the via (708, 1808, 2512, 3512). At 4050, the method includes forming a backside power rail (1006, 1806, 2804, 3804). At 4060, the method includes connecting the connection area (1014, 1814, 2814, 3814) of the via (708, 1808, 2512, 3512) to the backside power rail (1006, 1806, 2804, 3804).

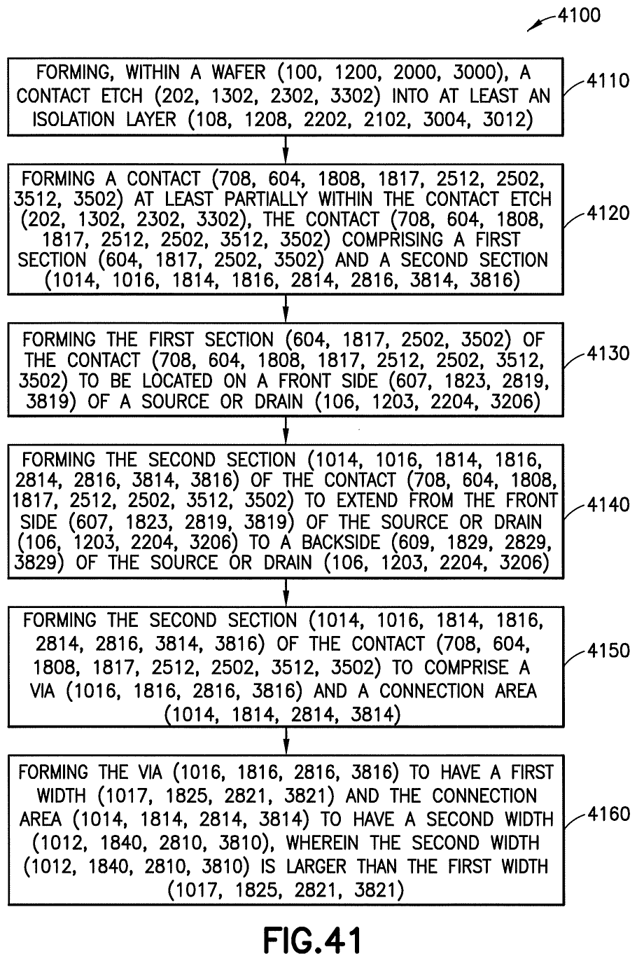

FIG. 41 is a logic flow diagram to form a device, based on the examples described herein. At 4110, the method includes forming, within a wafer (100, 1200, 2000, 3000), a contact etch (202, 1302, 2302, 3302) into at least an isolation layer (108, 1208, 2202, 2102, 3004, 3012). At 4120, the method includes forming a contact (708, 604, 1808, 1817, 2512, 2502, 3512, 3502) at least partially within the contact etch (202, 1302, 2302, 3302), the contact (708, 604, 1808, 1817, 2512, 2502, 3512, 3502) comprising a first section (604, 1817, 2502, 3502) and a second section (1014, 1016, 1814, 1816, 2814, 2816, 3814, 3816). At 4130, the method includes forming the first section (604, 1817, 2502, 3502) of the contact (708, 604, 1808, 1817, 2512, 2502, 3512, 3502) to be located on a front side (607, 1823, 2819, 3819) of a source or drain (106, 1203, 2204, 3206). At 4140, the method includes forming the second section (1014, 1016, 1814, 1816, 2814, 2816, 3814, 3816) of the contact (708, 604, 1808, 1817, 2512, 2502, 3512, 3502) to extend from the front side (607, 1823, 2819, 3819) of the source or drain (106, 1203, 2204, 3206) to a backside (609, 1829, 2829, 3829) of the source or drain (106, 1203, 2204, 3206). At 4150, the method includes forming the second section (1014, 1016, 1814, 1816, 2814, 2816, 3814, 3816) of the contact (708, 604, 1808, 1817, 2512, 2502, 3512, 3502) to comprise a via (1016, 1816, 2816, 3816) and a connection area (1014, 1814, 2814, 3814). At 4160, the method includes forming the via (1016, 1816, 2816, 3816) to have a first width (1017, 1825, 2821, 3821) and the connection area (1014, 1814, 2814, 3814) to have a second width (1012, 1840, 2810, 3810), wherein the second width (1012, 1840, 2810, 3810) is larger than the first width (1017, 1825, 2821, 3821).

Referring now to all the Figures, in one exemplary embodiment, a semiconductor device includes a contact comprising a first section and a second section; wherein the first section of the contact is located on a front side of a source or drain; wherein the second section extends from the front side of the source or drain to a backside of the source or drain; wherein the second section of the contact is comprised of a via and a connection area; wherein the via has a first width and the connection area has a second width, and wherein the second width is larger than the first width.

The semiconductor device may further include wherein the connection area of the contact connects back end of line metal to a backside power rail. The connection area of the contact connects the back end of line metal to the backside power rail without liner inside the contact. The semiconductor device may further include dielectric liner along at least one sidewall of the contact, the dielectric liner configured to isolate the contact from at least one epitaxial gate.

In another embodiment, a method includes forming, within a wafer, a via etch into at least an isolation layer; removing a portion of the isolation layer next to the etch, to increase a connection area of a via to be larger than a transfer section of the via; filling the via etch with metal to form the via; filling the removed portion of the isolation layer with metal to form the connection area of the via; forming a backside power rail; and connecting the connection area of the via to the backside power rail.

The method may further include forming a nitride spacer within the via etch; and continuing to form the via etch within a substrate layer of the wafer. The method may further include forming dielectric liner along at least one sidewall of the via etch, the dielectric liner configured to isolate the via from at least one epitaxial gate. The method may further include forming back end of line metal; connecting the back end of line metal to the backside power rail using the via without liner inside the via; and forming a contact to connect the via to at least one gate. The method may further include forming a first isolation layer of the isolation layer; and forming a second isolation layer of the isolation layer. The method may further include removing the first isolation layer; and filling the metal within an area formed with the removal of the first isolation layer to form the connection area of the via. The first isolation layer may be formed as part of the second isolation layer, or the first isolation layer may be formed within a substrate layer of the wafer deeper into the wafer than the second isolation layer. The method may further include adjusting a depth of the connection area with varying a thickness of a portion of the isolation layer being replaced.

In another embodiment, a method of forming a semiconductor device includes forming, within a wafer, a contact etch into at least an isolation layer; forming a contact at least partially within the contact etch, the contact comprising a first section and a second section; forming the first section of the contact to be located on a front side of a source or drain; forming the second section of the contact to extend from the front side of the source or drain to a backside of the source or drain; forming the second section of the contact to comprise a via and a connection area; and forming the via to have a first width and the connection area to have a second width, wherein the second width is larger than the first width.

The method may further include forming dielectric liner along at least one sidewall of the contact, the dielectric liner configured to isolate the contact from at least one epitaxial gate. The method may further include forming back end of line metal; connecting the back end of line metal to a backside power rail using the contact without liner inside the contact; and forming another contact to connect the via to at least one gate. The method may further include removing a portion of the isolation layer next to the etch, to increase the connection area of the contact; filling the contact etch with metal to form the contact; filling the removed portion of the isolation layer with metal to form the connection area of the contact; forming a backside power rail; and connecting the connection area of the via to the backside power rail. The method may further include adjusting a depth of the connection area with varying a thickness of a portion of an isolation layer being replaced. The method may further include forming a first isolation layer of the isolation layer; and forming a second isolation layer of the isolation layer. The method may further include removing the first isolation layer; and filling the metal within an area formed with the removal of the first isolation layer to form the connection area of the contact. The first isolation layer may be formed as part of the second isolation layer the first isolation layer may be formed within a substrate layer of the wafer deeper into the wafer than the second isolation layer.

In another embodiment, a semiconductor device includes a backside power rail; a source or drain; and a via to connect the source or drain to the backside power rail, the via comprising a transfer section having a first width and a connection area having a second width, the second width larger than the first width; wherein the connection area of the via is curved from at least a surface of the transfer section to a portion of the connection area that joins to the backside power rail, to vary the second width of the connection area towards the backside power rail.

The semiconductor device may further include a contact joined to a front side of the source or drain and to the via. The semiconductor device may further include dielectric liner along at least one sidewall of the via. The dielectric liner may be configured to isolate the via from the source or drain. A cross-section area of the connection area between the via and the backside power rail may be determined with a bottom area of an isolation layer. The transfer section may extend from a front side of the source or drain to a backside of the source or drain. The semiconductor device may include back end of line metal connected with the via to the backside power rail. The connection area of the contact may connect the back end of line metal to the backside power rail without liner. The connection area may be in a shape of a dome. The connection area of the via may be convexly curved from at least the surface of the transfer section to the portion of the connection area that joins to the backside power rail, to gradually increase the second width of the connection area towards the backside power rail.

References to a ‘computer’, ‘processor’, etc. should be understood to encompass not only computers having different architectures such as single/multi-processor architectures and sequential or parallel architectures but also specialized circuits such as field-programmable gate arrays (FPGAs), application specific circuits (ASICs), signal processing devices and other processing circuitry. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

The memory(ies) as described herein may be implemented using any suitable data storage technology, such as semiconductor based memory devices, flash memory, magnetic memory devices and systems, optical memory devices and systems, non-transitory memory, transitory memory, fixed memory and removable memory. The memory(ies) may comprise a database for storing data.

As used herein, circuitry may refer to the following: (a) hardware circuit implementations, such as implementations in analog and/or digital circuitry, and (b) combinations of circuits and software (and/or firmware), such as (as applicable): (i) a combination of processor(s) or (ii) portions of processor(s)/software including digital signal processor(s), software, and memory(ies) that work together to cause an apparatus to perform various functions, and (c) circuits, such as a microprocessor(s) or a portion of a microprocessor(s), that require software or firmware for operation, even if the software or firmware is not physically present. As a further example, as used herein, circuitry would also cover an implementation of merely a processor (or multiple processors) or a portion of a processor and its (or their) accompanying software and/or firmware. Circuitry would also cover, for example and if applicable to the particular element, a baseband integrated circuit or applications processor integrated circuit for a mobile phone or a similar integrated circuit in a server, a cellular network device, or another network device.

List of abbreviations, which abbreviations may be appended with each other or other characters using e.g. a dash or hyphen (“-”):
aSi amorphous silicon
ASIC application-specific integrated circuit
BEOL back end of line
BPR backside power rail, or buried power rail
BSPDN backside power delivery/distribution network
CA contact
CMP chemical mechanical planarization/polishing
epi epitaxial
FEOL front end of line
FPGA field-programmable gate array
HDP high density plasma
HM hard mask
ILD interlayer dielectric
MOL middle of line
NS nanosheet
POR process of record
RIE reactive-ion etch/etching
STI shallow trench isolation
VBPR via to buried/backside power rail

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A semiconductor device comprising:
a contact comprising a first section and a second section;
wherein the first section of the contact is located on a front side of a source or drain;
wherein the second section extends from the front side of the source or drain to a backside of the source or drain;
wherein the second section of the contact is comprised of a via and a connection area;
wherein the via has a first width and the connection area has a second width, and wherein the second width is larger than the first width.

2. The semiconductor device of claim 1, wherein the connection area of the contact connects back end of line metal to a backside power rail.

3. The semiconductor device of claim 2, wherein the connection area of the contact connects the back end of line metal to the backside power rail without liner inside the contact.

4. The semiconductor device of claim 1, further comprising dielectric liner along at least one sidewall of the contact, the dielectric liner configured to isolate the contact from at least one epitaxial gate.

5. A method comprising:
forming, within a wafer, a via etch into at least an isolation layer;
removing a portion of the isolation layer next to the etch, to increase a connection area of a via to be larger than a transfer section of the via;
filling the via etch with metal to form the via;
filling the removed portion of the isolation layer with metal to form the connection area of the via;
forming a backside power rail; and
connecting the connection area of the via to the backside power rail.

6. The method of claim 5, further comprising:
forming a nitride spacer within the via etch; and
continuing to form the via etch within a substrate layer of the wafer.

7. The method of claim 5, further comprising:
forming dielectric liner along at least one sidewall of the via etch, the dielectric liner configured to isolate the via from at least one epitaxial gate.

8. The method of claim 5, further comprising:
forming back end of line metal;
connecting the back end of line metal to the backside power rail using the via without liner inside the via; and
forming a contact to connect the via to at least one gate.

9. The method of claim 5, further comprising:
forming a first isolation layer of the isolation layer; and
forming a second isolation layer of the isolation layer.

10. The method of claim 9, further comprising:
removing the first isolation layer; and
filling the metal within an area formed with the removal of the first isolation layer to form the connection area of the via.

11. The method of claim 10,
wherein the first isolation layer is formed as part of the second isolation layer; or
wherein the first isolation layer is formed within a substrate layer of the wafer deeper into the wafer than the second isolation layer.

12. The method of claim 5, further comprising:
adjusting a depth of the connection area with varying a thickness of a portion of the isolation layer being replaced.

13. A semiconductor device comprising:
a backside power rail;
a source or drain; and
a via to connect the source or drain to the backside power rail, the via comprising a transfer section having a first width and a connection area having a second width, the second width larger than the first width;
wherein the connection area of the via is curved from at least a surface of the transfer section to a portion of the connection area that joins to the backside power rail, to vary the second width of the connection area towards the backside power rail.

14. The semiconductor device of claim 13, further comprising:
a contact joined to a front side of the source or drain and to the via.

15. The semiconductor device of claim 13, further comprising dielectric liner along at least one sidewall of the via, wherein the dielectric liner is configured to isolate the via from the source or drain.

16. The semiconductor device of claim 13, wherein a cross-section area of the connection area between the via and the backside power rail is determined with a bottom area of an isolation layer.

17. The semiconductor device of claim 13, wherein the transfer section extends from a front side of the source or drain to a backside of the source or drain.

18. The semiconductor device of claim 13, further comprising back end of line metal connected with the via to the backside power rail, wherein the connection area of the contact connects the back end of line metal to the backside power rail without liner.

19. The semiconductor device of claim 13, wherein the connection area is in a shape of a dome.

20. The semiconductor device of claim 13, wherein the connection area of the via is convexly curved from at least the surface of the transfer section to the portion of the connection area that joins to the backside power rail, to gradually increase the second width of the connection area towards the backside power rail.
